(19) United States
(12) Patent Application Publication
(10) Pub. No.: US 2014/0008609 A1
(43) Pub. Date: Jan. 9, 2014

(54) LIGHT EMITTING DEVICE WITH NANOROD THEREIN AND THE FORMING METHOD THEREOF

(71) Applicant: Epistar corporation, Hsinchu city (TW)

(72) Inventors: Ching Hsueh Chiu, Hsinchu city (TW); Po Min Tu, Hsinchu city (TW); Hao Chung Kuo, Hsinchu city (TW); Chun Yen Chang, Hsinchu city (TW); Shing Chung Wang, Hsinchu city (TW)

(21) Appl. No.: 13/933,220

(22) Filed: Jul. 2, 2013

(30) Foreign Application Priority Data
Jul. 6, 2012 (TW) 101124351

(51) Int. Cl. H01L 33/24

(52) U.S. Cl. CPC H01L 33/24
USPC 257/13; 438/39

(57) ABSTRACT

A method of fabricating a light emitting device, comprising: providing a substrate; forming an undoped semiconductor layer on the substrate; forming a patterned metal layer on the undoped semiconductor layer; using the patterned metal layer as a mask to etch the undoped semiconductor layer and forming a plurality of nanorods on the substrate; and forming an light emitting stack on the plurality of nanorods to form a plurality of voids between the light emitting stack and the plurality of nanorods.

### RELATED APPLICATION

This application claims the priority to and the benefit of TW application Ser. No. 101124351 filed on Jul. 06, 2012; the contents of which are incorporated herein by reference in its entirety.

### BACKGROUND

1. Technical Field

The present disclosure disclosed a light emitting device, which is especially related to a light emitting device with nanorods and its forming method.

2. Description of the Related Art

The spectrum of the high brightness GaN light emitting diode (LED) is from green light to ultraviolet that can be used in full-color display monitor, short-haul optical communication, traffic signal, backlight of LCD or lighting system. The optical power and external quantum efficiency need to be improved in order to fit the need of next generation of the using of the projection, head lamp of car or high level lighting system. Generally, if the current injection efficiency was 100%, the external quantum efficiency can be viewed as the product of the internal quantum efficiency and the light extraction efficiency. However, the epitaxial layer mainly composed of GaN has higher threading dislocation densities (TDD) of 10⁸-10¹⁰/cm² because of larger lattice mismatch and the unmatched thermal expansion coefficient. The higher threading dislocation densities (TDD) deteriorate the internal quantum efficiency. In order to solve the problem of the lattice mismatch of GaN epitaxially grown on the sapphire substrate, some methods have been discussed in publications, such as epitaxial lateral overgrowth, defect-selective passivation [symbol] microscale SiN, patterned mask of SiO₂, or patterned sapphire substrate (PSS). Besides, the high reflectivity of GaN limits the escape angle and decreases the light extraction efficiency decreased.

### SUMMARY OF THE DISCLOSURE

A method of fabricating a light emitting device, comprising: providing a substrate; forming an undoped semiconductor layer on the substrate; forming a patterned metal layer on the undoped semiconductor layer; using the patterned metal layer as a mask to etch the undoped semiconductor layer and forming a plurality of nanorods on the substrate; and forming an light emitting stack on the plurality of nanorods to form a plurality of voids between the light emitting stack and the plurality of nanorods.

A light emitting device, comprising: a substrate; a plurality of nanorods comprising a plurality of undoped semiconductor epitaxial rods on the substrate; and an light emitting stack formed and covering on the plurality of nanorods, and a plurality of voids formed between the light emitting stack and the plurality of nanorods.

### BRIEF DESCRIPTION OF DRAWINGS

The accompanying drawings are included to provide easy understanding of the application, and are incorporated herein and constitute a part of this specification. The drawings illustrate embodiments of the application and, together with the description, serve to illustrate the principles of the application.

FIGS. 1 to 6 illustrate a process flow of a method of fabricating a light emitting device in accordance with one embodiment of the present disclosure.

FIG. 7 illustrates the difference of the electron microscope pictures of the conventional device and the device disclosed in one embodiment of the present disclosure.

FIG. 8 illustrates the difference of the raman spectrogram of the conventional device and the device disclosed in one embodiment of the present disclosure.

FIG. 9(a) illustrates the difference of the L-I-V curve of the conventional device and the device disclosed in one embodiment of the present disclosure.

FIG. 9(b) illustrates the difference of the reverse I-V curve of the conventional device and the device disclosed in one embodiment of the present disclosure.

### DETAILED DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

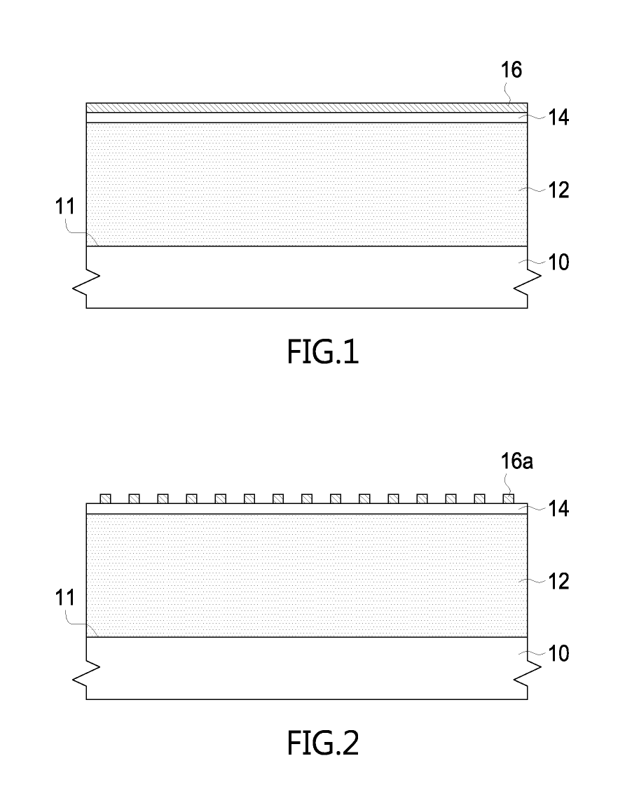

The present disclosure describes a light emitting device and a method of fabricating the light emitting device. In order to have a thorough understanding of the present disclosure, please refer to the following description and the illustrations of FIGS. 1 to FIG. 9(b).

FIGS. 1 to 6 illustrate a process flow of a method of fabricating a light emitting device 300 of one embodiment of the present disclosure. FIG. 1 illustrates a substrate 10, an undoped semiconductor layer 12 formed on the substrate 10, an oxide layer 14 formed on the undoped semiconductor layer 12, and a metal layer 16 formed on the oxide layer 14. In the embodiment, the substrate 10 has a substantially flat surface 11. The substrate 10 can be a growth or carrying base for the undoped semiconductor layer 12. The material of the substrate 10 comprises an electrically conductive substrate, electrically insulating substrate, transparent substrate. The material of the electrically conductive substrate can be metal such as Ge, or GaAs, InP, SiC, Si, LiAlO₂, ZnO, GaN and AlN. The material of the transparent substrate can be chosen from sapphire (Al₂O₃), LiAlO₂, ZnO, GaN, AlN, glass, diamond, CVD diamond, diamond-like carbon (DLC), spinel (MgAl₂O₃), SiOₓ, or LiGaO₂.

In one embodiment, the undoped semiconductor layer 12 is formed on the substantially flat surface 11 of the substrate 10 by epitaxial method with the thickness of 1-5 μm, 1-4 μm, 1-3 μm or 1-2 μm. In one embodiment, the material of the undoped semiconductor layer 12 comprises one element selected from the group consisting of Ga, Al, In, As, P, N, Si, and the combination thereof. In one embodiment, the undoped semiconductor layer 12 can be an undoped-GaN layer.

Following, an oxide layer 14 is formed on the undoped semiconductor layer 12 by the method of plasma enhanced chemical vapor deposition (PECVD). In one embodiment, the thickness of the oxide layer 14 can be 150-300 nm. In one embodiment, the thickness of the oxide layer 14 can be 200 nm. In one embodiment, the material of the oxide layer 14 can be SiO₂. Following, a metal layer 16 can be formed on the oxide layer 14 by evaporation. In one embodiment, the material of the oxide layer 14 can be Ni, or Cr.

Following, the structure shown in FIG. 1 is treated by a thermal treatment such as rapid thermal annealing (RTA) at 800-900° C. in the environment of nitrogen for 1-3 minutes.

Following, FIG. 2 illustrates a process of patterning the metal layer 16 to form a patterned metal layer 16a by the method of photolithography and etching process.

Following, FIG. 3 illustrates the cross-sectional view of the plurality of nanorods 20 formed on the substrate 10. By using the patterned metal layer 16a as etching mask and the undoped semiconductor layer 12 as etching stop layer, the oxide layer 14 is etched by dry etching and partial of the oxide layer 14 is removed and a plurality of oxide rods 14′ is formed. In one embodiment, the dry etching can be a reaction ion etching (RIE) and the etching gas can be CF₄ with the etching rate of 66 nm/min for 2-5 minutes.

FIG. 3 further illustrates another dry etching performed on the undoped semiconductor layer 12 to remove partial of the undoped semiconductor layer 12 and form a plurality of undoped semiconductor rods 12′ by using the patterned metal layer 16a and the plurality of oxide rods 14′ as etching mask and the substrate 10 as etching stop layer following the process of etching the oxide layer 14. In one embodiment, the dry etching used on the undoped semiconductor layer 12 can be an inductive coupled plasma (ICP) with the mixture of Cl₂ and Ar wherein the gas flow rate of Cl₂ is 5 sccm and Ar is 50 seem so the etching rate is about 58 nm/min and the etching time is 30-40 minutes. In one embodiment, both the etching power of the reaction ion etching and the inductive coupled plasma are 100 W.

Following the dry etching process of FIG. 3, FIG. 4 illustrates the structure shown in FIG. 3 is immersed into a heated acid solution and the patterned metal layer 16a is removed by the heated acid solution. A plurality of the nanorods 20 is formed with oxide rods 14′ and the undoped semiconductor rods 12′ on the substrate 10. In one embodiment, the acid solution can be a heated nitric acid while the immersing time is 5-10 minutes and the acid temperature is 100° C.

In one embodiment, the height of the nanorods 20 formed with oxide rods 14′ and the undoped semiconductor rods 12′ shown in FIG. 4 can be 1-3 μm. The average diameter of the nanorods 20 can be 250-300 nm, 250-400 nm, or 250-500 nm. The density of the nanorods 20 can be 1×10⁸˜9×108/cm2. Because the structure of the nanorods 20 is long and thin, the lateral growth rate of the sidewall of the nanorod 20 in the following epitaxial process is faster and having better stress relief.

Following, FIG. 5 illustrates a light emitting stack 30 including a first conductive-type semiconductor layer 32, an active layer 34, and a second conductive-type semiconductor layer 36 formed on the plurality of the nanorods 20 by the process of metal organic chemical vapor deposition (MOCVD). A first conductive-type semiconductor layer 32 is formed on the plurality of the nanorods 20. In one embodiment, the first conductive-type semiconductor layer 32 is formed on the M-plane (1010) of the nanorods 20 and the R-plane (1102) close to the top of the nanorods 20. By the process, it makes the thickness of the nanorods 20a thicker than the nanorods 20 shown in FIG. 4. Because the growth rate of the semi-polar plane of the nanorod 20 is larger than the growth rate of the non-polar plane of the nanorod 20, the growth rate of the first conductive-type semiconductor layer 32 formed on the nanorods 20 is enhanced and a plurality of voids 20b (as shown in FIG. 6) is also formed between the plurality of nanorods 20. The length of the plurality of the voids 20b can be up to 0.5-1 μm and the voids 20b can be deemed as being embedded inside the light emitting device 300. The air inside the voids 20b can be a light guiding media so the light extraction efficiency of the light emitting device 300 can be improved.

Following, FIG. 6 illustrates an active layer 34 and a second conductive-type semiconductor layer 36 formed on the first conductive-type semiconductor layer 32 subsequently and the light emitting device 300 with the plurality of the voids 20b is formed. In this structure, the plurality of the voids 20b is formed between the light emitting stack 30 and the plurality of the nanorods 20. The air inside the plurality of the voids 20b can be a light guiding media so the light extraction efficiency of the light emitting device 300 can be improved.

The first conductive-type semiconductor layer 32 and the second conductive-type semiconductor layer 36 are different in electricity, polarity or dopant, or are different semiconductor materials used for providing electrons and holes, wherein the semiconductor material can be single semiconductor material layer or multiple semiconductor material layers. The polarity can be chosen from any two of p-type, n-type and i-type. The material of the first conductive-type semiconductor layer 32, the active layer 34, and the second conductive-type semiconductor layer 36 comprises one element selected from the group consisting of Ga, Al, In, As, P, N, Si, and the combination thereof.

The active layer 34 is disposed between the first conductive-type semiconductor layer 32 and the second conductive-type semiconductor layer 36 and can convert the voltage applied to the epitaxial semiconductor structure into the light energy, and the light can be emitted in the form of omnidirectional emission to every direction. The structure of the active layer 34 can be single heterostructure (SH), double heterostructure (DH), double-side double heterostructure (DDH) or multi-quantum well (MQW), wherein the wavelength of the light emitted from the active layer 34 can be changed by adjusting the number of the pairs of MQW. The material of the active layer 34 can be AlGanInP-based semiconductor, AlGaInN-based semiconductor, or ZnO-based semiconductor.

The first conductive-type semiconductor layer 32, the active layer 34, and the second conductive-type semiconductor layer 36 can be formed by a metal organic chemical vapor deposition (MOCVD) process. In one embodiment, the first conductive-type semiconductor layer 32 can be an n-type semiconductor layer, such as n-GaN, the second conductive-type semiconductor layer 36 can be a p-type semiconductor layer, such as p-GaN and the active layer 34 can be a multi-quantum well (MQW).

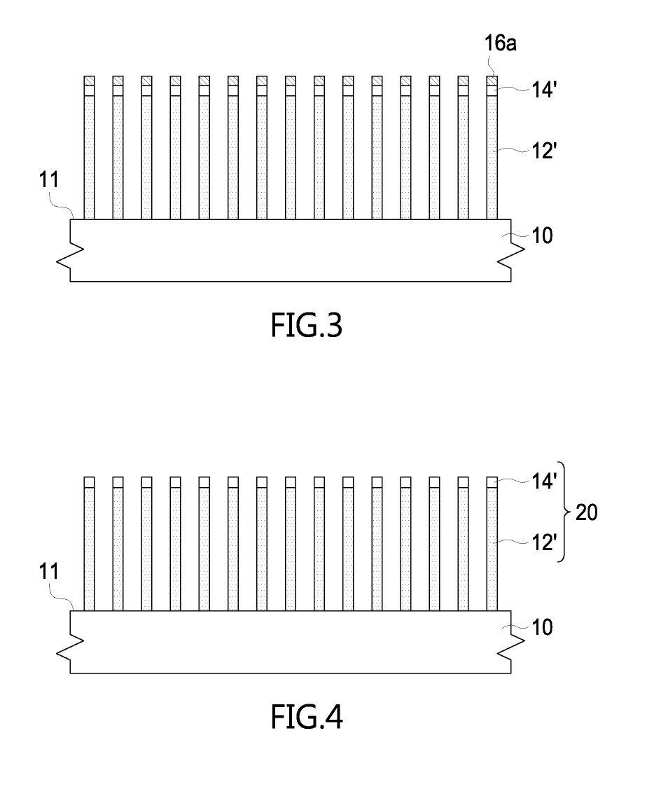

FIG. 7 illustrates the difference of the electron microscope pictures of the conventional device and the device disclosed in one embodiment of the present disclosure. The dislocation density of the conventional GaN-based light emitting device is 10⁸˜10⁹/cm². In one embodiment of the present disclosure with the plurality of the nanorods 20, the dislocation density is 5×10⁷/cm². The difference of the dislocation density in the present disclosure and the conventional device is because of the misfit vertical to C-axis and the dislocation bending of the plurality of the voids 20b formed between the plurality of the nanorods 20.

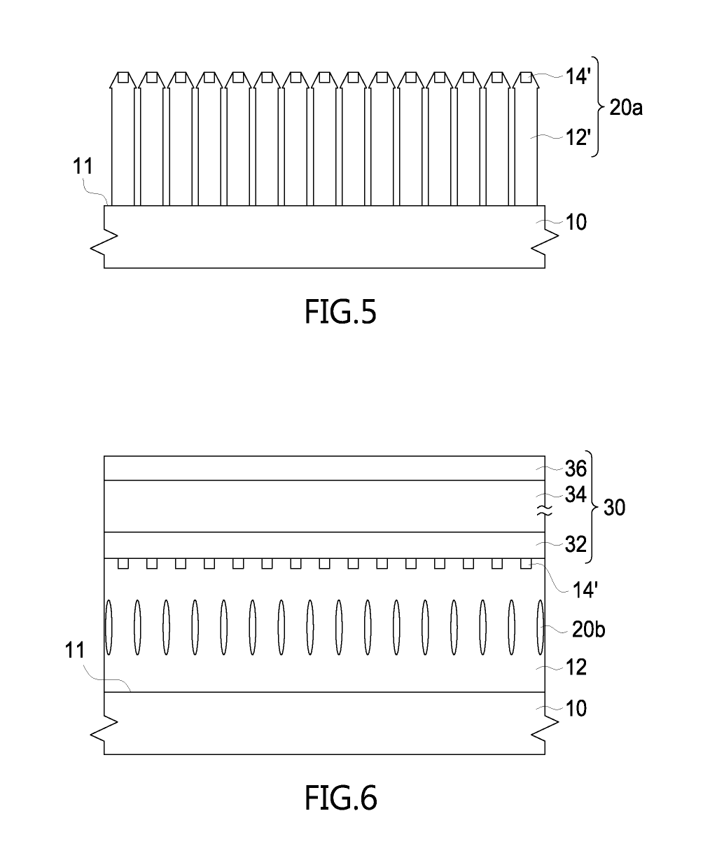

FIG. 8 illustrates the difference of the raman spectrogram of the conventional device and the device disclosed in one embodiment of the present disclosure. In one embodiment, the light emitting stack 30 includes GaN based material. FIG. 8 illustrates the crest of the present disclosure with nanordos (GaN on NRs) is 568/cm, and the, compressive stress is 0.88 GPa. The crest of the conventional device without nanordos (GaN on sapphire) is 570.4/cm and the compressive stress is 1.73 GPa. As the crest and the compressive stress shown in FIG. 8, the residual stress of the light emitting stack formed on the plurality of nanorods is reduced to have better stress relief. The crack of the light emitting device is also reduced and the stability of the light emitting device is increased.

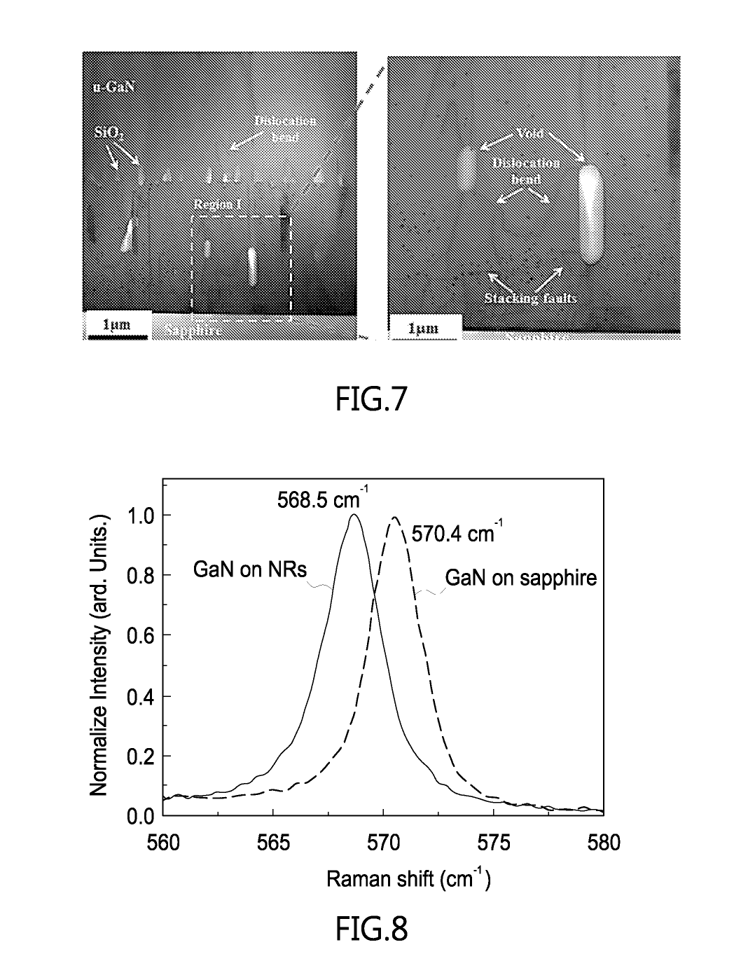

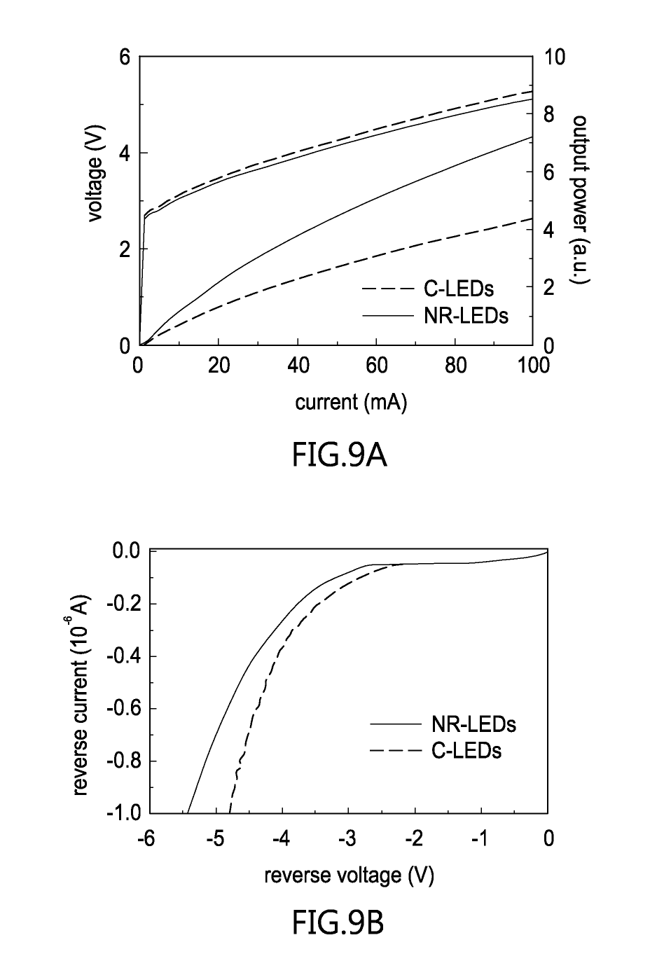

FIG. 9(a) illustrates the difference of the L-I-V curve of the conventional device and the device disclosed in one embodiment of the present disclosure. In one embodiment, the light emitting stack includes GaN material. At a current of 20 mA, the forward voltage of the embodiment in the present disclosure (NR-LEDs) and the conventional device without nanorods (C-LEDs) is 3.37V and 3.47V respectively, and the output power of the embodiment in the present disclosure (NR-LEDs) and the conventional device without nanorods (C-LEDs) is 21.6 mW and 13.1 mW respectively. The improvement of the gain characteristics of the L-I-V curve is based on the following reasons. First is the reducing of the threading dislocation density (TDD). The non-radiative recombination is reduced and the efficiency of forming photons is increased because of the reduction of the threading dislocation density. Second is the increasing of the light extraction of the light emitting device 300 by the light scattering effect from the microscale or nanoscale voids 20b and the oxide rods 14. Besides, FIG. 9(b) illustrates the difference of the reverse I-V curve of the conventional device and the embodiment in the present disclosure. The leakage current of the embodiment in the present disclosure (NR-LEDs) is smaller than the conventional device without nanorods (C-LEDs) in a reverse bias.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. A method of fabricating a light emitting device, comprising:
providing a substrate;
forming an undoped semiconductor layer on the substrate;
forming a patterned metal layer on the undoped semiconductor layer;
using the patterned metal layer as a mask to etch the undoped semiconductor layer and forming a plurality of nanorods on the substrate; and
forming an light emitting stack on the plurality of nanorods to form a plurality of voids between the light emitting stack and the plurality of nanorods.

2. The method of fabricating the light emitting device of claim 1, further comprising a step of forming a metal layer on the undoped semiconductor layer and etching the metal layer to form a patterned metal layer.

3. The method of fabricating the light emitting device of claim 1, further comprising forming an oxide layer between the metal layer and the undoped semiconductor layer, and using the patterned metal layer as a mask to etch the oxide layer and the undoped semiconductor layer to form a plurality of nanorods comprising the oxide layer and the undoped semiconductor layer on the substrate.

4. The method of fabricating the light emitting device of claim 3, wherein the etching of the oxide layer is by reaction ion etching (RIE).

5. The method of fabricating the light emitting device of claim 3, wherein the etching of the undoped semiconductor layer is by inductive coupled plasma (ICP).

6. The method of fabricating the light emitting device of claim 3, wherein the substrate having a substantially flat surface and the undoped semiconductor layer is formed on the substantially flat surface.

7. The method of fabricating the light emitting device of claim 1, wherein the light emitting stack comprising a first conductive-type semiconductor layer formed on the plurality of the nanorods, an active layer form on the first conductive-type semiconductor layer and a second conductive-type semiconductor layer formed on the active layer.

8. The method of fabricating the light emitting device of claim 1, wherein the material of the light emitting stack and the undoped semiconductor layer comprises one element selected from the group consisting of Al, Ga, In, As, P, N and the combination thereof.

9. A light emitting device, comprising:
a substrate;
a plurality of nanorods comprising a plurality of undoped semiconductor epitaxial rods on the substrate; and
a light emitting stack formed and covering on the plurality of nanorods, and a plurality of voids formed between the light emitting stack and the plurality of nanorods.

10. The light emitting device of claim 9, further comprising a plurality of oxide rods formed on the plurality of the undoped semiconductor epitaxial rods to form the plurality of nanorods.

11. The light emitting device of claim 9, wherein the material of the light emitting stack and the undoped semiconductor epitaxial rods comprises one element selected from the group consisting of Al, Ga, In, As, P, N and the combination thereof.

12. The light emitting device of claim 9, wherein the light emitting stack comprising a first conductive-type semiconductor layer formed on the first plurality of the nanorods, an active layer form on the first conductive-type semiconductor layer and a second conductive-type semiconductor layer formed on the active layer.

13. The light emitting device of claim 9, wherein the height of the nanorods can be 0.5-1 μm.

14. The light emitting device of claim 9, wherein the average diameter of the nanorods can be 250-500 nm.

15. The light emitting device of claim 9, wherein the density of the nanorods can be 1×10⁸˜9×10⁸.

16. The light emitting device of claim 10, wherein the height of the nanorods can be 1-3 μm.

17. The light emitting device of claim 10, wherein the average diameter of the nanorods can be 250-500 nm.

18. The light emitting device of claim 10, wherein the density of the nanorods can be 1×10⁸˜9×10⁸.

19. The light emitting device of claim 9, further comprising a first electrode formed on the first conductive-type semiconductor layer

20. The light emitting device of claim 9, further comprising a second electrode formed on the second conductive-type semiconductor layer or the substrate.
